(19) United States
(12) Patent Application Publication
(10) Pub. No.: US 2017/0069265 A1
(43) Pub. Date: Mar. 9, 2017

(54) Display Drive Device and AMOLED Display Comprising the Drive Device

(71) Applicant: EverDisplay Optronics (Shanghai) Limited, Shanghai (CN)

(72) Inventor: Sisi Zhou, Shanghai (CN)

(21) Appl. No.: 15/259,651

(22) Filed: Sep. 8, 2016

(30) Foreign Application Priority Data
Sep. 9, 2015 (CN) 201510570768.7

(51) Int. Cl. G09G 3/3233

(52) U.S. Cl. CPC G09G 3/3233; G09G 2310/061; G09G 2310/08; G09G 2300/0814; G09G 2310/0286; G09G 2300/0819; G09G 2320/045

(57) ABSTRACT

The invention relates to the field of display, more particularly, to a Gate on Array as well as the display thereof, and to a multistage shift register composed of basic drive circuits. In multistage drive modules, an output signal of any stage of the drive modules is served as a reset signal of an adjacent previous-stage drive module, and at the same time, as an input signal of an adjacent next-stage drive module, the combination of the output signals generated by multistage drive modules constitutes a series of non-overlapping sequence pulse signals.

### CROSS-REFERENCE TO RELATED APPLICATIONS

The present application claims priority to and the benefit of Chinese Patent Application No. CN 201510570768.7, filed on Sep. 9, 2015, the entire content of which is incorporated herein by reference.

### BACKGROUND OF THE INVENTION

Field of the Invention

The invention relates to the field of display, more particularly, to a Gate on Array as well as the display devices thereof, and to a multistage shift register composed of basic drive circuits.

Description of the Related Art

In the traditional prior art, with the PMOLED (passive matrix organic light-emitting diode) being widely used in displays by the manufacture, if we try to increase the panel size of the displays to meet the requirements of the consumers, we need to reduce the drive time of a single pixel, therefore the transient current is increased, and the power consumption and the voltage drop in ITO line may increase, thus the working efficiency of the displays is reduced. Alternatively, the manufacture also designs the AMOLED (active matrix organic light-emitting diode), which progressively scan input OLED current by switch tubes, to solve the problems effectively. The AMOLED is more and more widely adopted by high performance display devices due to the advantages of high brightness, wide angle of view and fast response speed. The GOA (Gate on Array) integrates the gate switch circuits into an array substrate, so as to realize the high integration of the drive circuits.

FIG. 1 is a design scheme of a typical GOA circuit in prior art, and the drive circuit is substantially made of seven thin-film transistors (TFT), includes PMOS transistors M10˜M16 shown in FIG. 1, the drive circuit further comprises two capacitors C10 and C20. One of the problems the prior art faced with is that the number of transistors used in the GOA drive circuit is so many that the layout area thereof is increased, which cannot meet the design requirements of narrow frames of displays obviously, and the excessive amounts of transistors causes the yield significantly to decrease. And another issue is that in the GOA drive circuit, the M13 is basically in an on-state during a frame period, however the MOS device being in an on-state for a long time would be easy to cause the threshold voltage of the M13 to drift slightly, so that the GOA circuit goes abnormal. The invention will introduce the design of drive circuits with the same or even less transistors, to avoid such problems.

### SUMMARY OF THE INVENTION

In order to solve the above-mentioned technical problems, the application provides a display drive device, and the drive device comprises a plurality of drive modules which are in multiple stages, each of the drive modules comprising:
a first transistor and a second transistor connected to the first transistor in series, and a first node configured at an interconnection point of the second transistor and the first transistor;
a third transistor configured with a control terminal, and the first node being connected to the control terminal of the third transistor;
a fourth transistor and a fifth transistor connected to the fourth transistor in parallel, and a second node configured at an interconnection point of the fifth transistor and the fourth transistor;
a first capacitor, connected between the first node and the second node;
wherein, the third transistor is connected to the second node, so that an output signal is generated at the second node.

As a preferred embodiment, in the above-mentioned display drive device, each of the drive modules further comprising:
a second capacitor and a sixth transistor connected to the second capacitor in series, a control terminal of the sixth transistor being connected to the first node; and
a third node configure at an interconnection point of a first end of the sixth transistor and a second end of the second capacitor, and the third node being connected to a control terminal of the second transistor and a control terminal of the fourth transistor respectively;
a reference voltage end, connected to a second end of the second transistor, a second end of the fourth transistor, a second end of the fifth transistor and a second end of the sixth transistor respectively;
wherein a first end of the second capacitor is connected to a first end of the third transistor, and a second end of the third transistor is connected to the second node.

As a preferred embodiment, in the above-mentioned display drive device:
a second end of the first transistor and a first end of the second transistor are connected to the first node, and a first end of the first transistor is used to receive an input signal, a control terminal of the first transistor and a control terminal of the fifth transistor are connected to a first clock control terminal of each of the drive modules, the first end of the second capacitor and the first end of the third transistor are connected to a second clock control terminal of each of the drive modules.

As a preferred embodiment, in the above-mentioned display drive device, between two adjacent of the plurality of drive modules:
an output signal end of a previous-stage drive module is connected to the first end of the first transistor of a next-stage drive module, so that an output signal of the previous-stage drive module is used for an input signal of the next-stage drive module.

As a preferred embodiment, in the above-mentioned display drive device, each of the drive modules further comprising:
a seventh transistor, connected to the second transistor in parallel;
wherein, a first end of the seventh transistor is connected to the first node, and a second end of the seventh transistor is connected to the reference voltage end.

As a preferred embodiment, in the above-mentioned display drive device, between two adjacent of the plurality of drive modules:
an output signals of a previous-stage drive module is transmitted to the first end of the first transistor of a next-stage drive module, so that the output signal is used as an input signal of the next-stage drive module; and
an output signal of the next-stage drive module is transmitted to a control terminal of the seventh transistor of the previous-stage drive module, so that the output signal is used as reset signals of the next-stage drive module.

As a preferred embodiment, in the above-mentioned display drive device, between two adjacent of the plurality of drive modules:
the first clock control terminal of a previous-stage drive module is driven by a first clock signal, and the second clock control terminal of the previous-stage drive module is driven by a second clock signal inverted from the first clock signal; and
the first clock control terminal of a next-stage drive module is driven by the second clock signal, and the second clock control terminal of the next-stage drive module is driven by the first clock signal.

As a preferred embodiment, in the above-mentioned display drive device, among the plurality of drive modules arranged in series:
the first clock control terminals of the plurality of drive modules in odd are driven by a first clock signal, and the second clock control terminals of the plurality of drive modules in odd are driven by a second clock signal complemented to the first clock signal; and
the first clock control terminals of the plurality of drive modules in even are driven by the second clock signal, and the second clock control terminals of the plurality of drive modules in even are driven by the first clock signal.

As a preferred embodiment, in the above-mentioned display drive device:
the first transistor, the second transistor, the third transistor, the fourth transistor, the fifth transistor and the sixth transistor are all PMOS (P-channel Metal Oxide Semiconductor) thin-film transistors.

As a preferred embodiment, in the above-mentioned display drive device:
the first transistor, the second transistor, the third transistor, the fourth transistor, the fifth transistor, the sixth transistor and the seventh transistor are all PMOS thin-film transistors.

The application further provides an AMOLED display, which may comprise any one of the above-mentioned display drive devices, the AMOLED display further comprising:
an array substrate provided with a display area and a GOA area;
a display module configured on the display area of the array substrate; and
the display drive device being configured on the GOA area of the array substrate, so as to drive the display module to emit light.

### BRIEF DESCRIPTIONS OF THE DRAWINGS

The accompanying drawings, together with the specification, illustrate exemplary embodiments of the present disclosure, and, together with the description, serve to explain the principles of the present invention.

FIG. 1 is a basic framework of a GOA circuit in the prior art;

FIG. 2 is a circuit structure of a drive module of an optional embodiment of the invention;

FIG. 3 is a diagram of a plurality of drive modules connected in series which are in multiple stages based on FIG. 2;

FIG. 4 is a diagram of the sequential control program;

FIGS. 5A-5E are response actions of each transistor of the drive module based on FIG. 2 during the stage of performing the sequential control program;

FIG. 6 is a circuit structure of a drive module of another optional embodiment of the invention;

FIG. 7 is a diagram of a plurality of drive modules connected in series which are in multiple stages based on FIG. 6;

FIGS. 8A-8E are response actions of each transistor of the drive module based on FIG. 6 during the stage of performing the sequential control program.

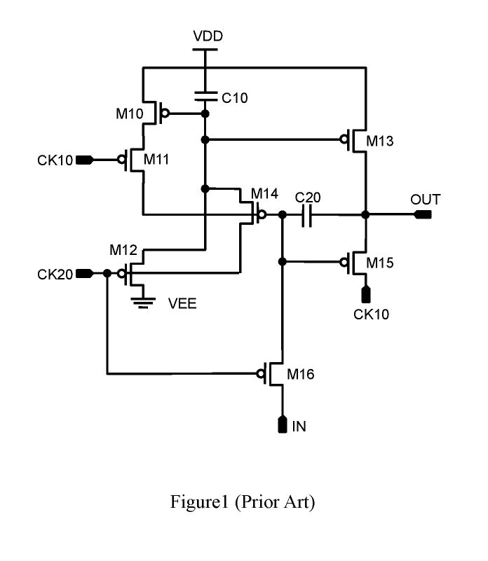

### DETAILED DESCRIPTION

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the term “plurality” means a number greater than one.

Hereinafter, certain exemplary embodiments according to the present disclosure will be described with reference to the accompanying drawings.

In this field, the Gate on Array (GOA) primarily integrates gate switch circuits into a same array substrate, so as to realize the high integration of the drive circuits, which is an excellent choice in both material saving and process steps reducing, especially the AMOLED is mainly based on low temperature polycrystalline silicon technology, thin-film transistors (TFT) of drive panel have high mobility, which can be beneficial to the integration of GOA circuits.

### Embodiment 1

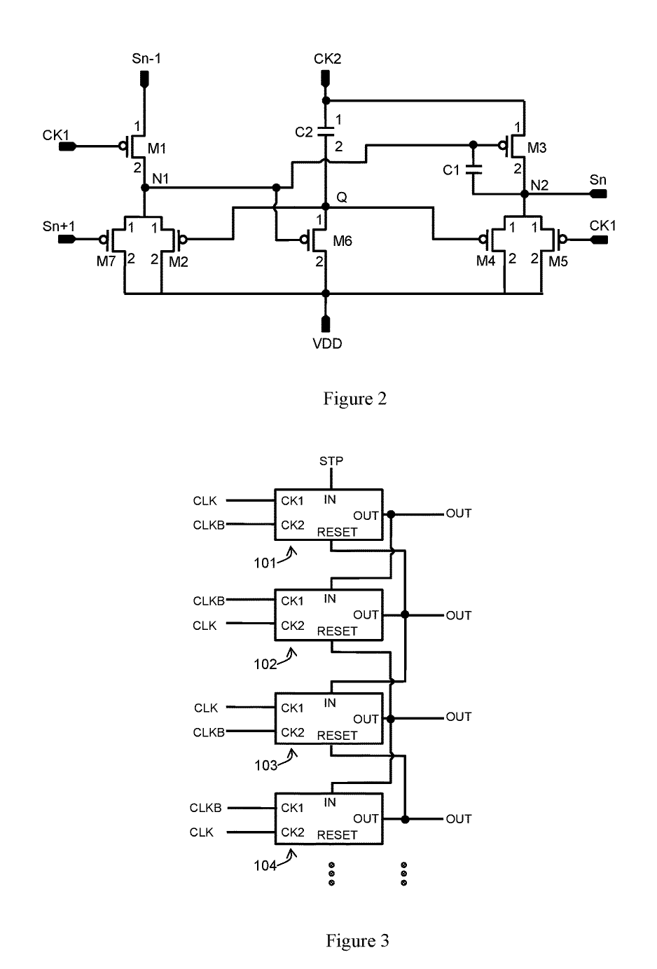

The embodiment provides a display drive device, may comprise a GOA drive circuit shown in FIG. 2 according to the invention. The drive module or the circuit mainly comprises first transistor to seventh transistor M1-M7. The second transistor M2 and the seventh transistor M7 are connected in parallel, and a first end of the second transistor M2 and a first end of the seventh transistor M7 are interconnected at a first common node N1, a second end of the second transistor M2 and a second end of the seventh transistor M7 are interconnected and the intersection is connected to a first reference voltage VDD. The second transistor M2 and the seventh transistor M7 are connected in parallel, then the two parallel transistors are connected with the first transistor M1 in series, a second end of the first transistor M1 is connected to the first common node N1. In addition, the fourth transistor M4 and the fifth transistor M5 are connected in parallel, and a first end of the fourth transistor M4 and a first end of the fifth transistor M5 are interconnected at a second common node N2, a second end of the fourth transistor M4 and a second end of the fifth transistor M5 are interconnected and the intersection is connected to the first reference voltage VDD. The fourth transistor M4 and the fifth transistor M5 are connected in parallel and then the two parallel transistors are connected with the third transistor M3 in series, a second end of the third transistor M3 is connected to the second common node N2.

In addition, the control terminal of the third transistor M3 is connected to the first common node N1, and a first capacitor C1 is connected between the second common node N2 and the first common node N1, we assume the drive module will finally output the output signal Sₙ thereof in the second common node N2. Furthermore, the drive module is also provided with a second capacitor C2 and a sixth transistor M6 connected to the second capacitor C2 in series, a first end of the second capacitor C2 and a first end of the third transistor M3 interconnected to the first end of the second capacitor C2, a second end of the second capacitor C2 and a first end of the sixth transistor M6 connected to the second end of the second capacitor C2 at a third common node Q, and the control terminal of the second transistor M2 and the control terminal of the fourth transistor M4 are connected to the third common node Q, and a control terminal of the sixth transistor M6 is connected to the first common node N1, a second end of the sixth transistor M6 is connected to the first reference voltage VDD. In some embodiments, the first transistor to the seventh transistor M1-M7 here may choose P type thin-film transistors (TFT). In addition, the embodiment further assumes the control terminals of the first transistor to the seventh transistor M1˜M7 may be, for example gates, and the first ends of these transistors may be, for example sources (or drains), while the second ends are drains (or sources), as an electronic switch, the control terminal of the transistor can control the first end and the second end thereof to be switched on or be turned off.

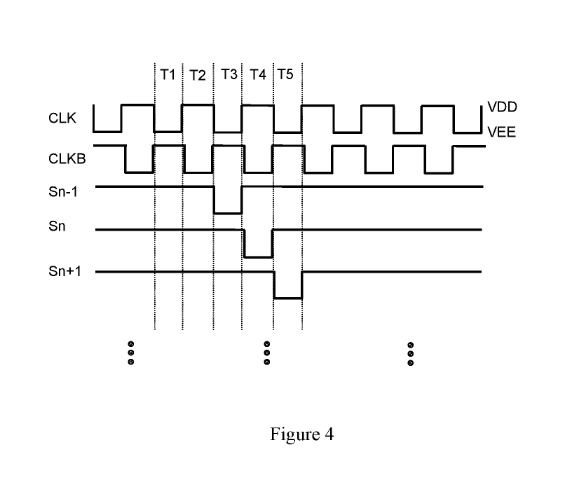

Refer to FIG. 2, in each drive module, the control terminal of the first transistor M1 and the control terminal of the fifth transistor M5 are connected with each other, and are interconnected to the first clock control terminal CK1 of the drive module, and the first end of the third transistor M3 and the first end of the second capacitor C2 are interconnected to the second clock control terminal CK2 of the drive module. In a drive mode, when the first clock signal CLK is input to the first clock control terminal CK1, that is, input to the gate control terminal of the first transistor M1 and to the gate control terminal of the fifth transistor M5, an inverted signal or in other words a complementary signal of the first clock signal, that is, a second clock signal CLKB is also required to be input to the second clock control terminal CK2 synchronously, that is, input to the first end of the third transistor M3 and to the first end of the second capacitor C2, for example, in FIG. 3, a drive module 101 is suitable for such a connection mode or drive mode of the first and the second clock control terminals CK1 and CK2. Another drive mode is that, when the second clock signal CLKB is input to the first clock control terminal CK1, that is, input to the gate control terminal of the first transistor M1 and to the gate control terminal of the fifth transistor M5, the first clock signal CLK is also required to be input to the second clock control terminal CK2 synchronously, that is, input to the first end of the third transistor M3 and to the first end of the second capacitor C2, for example, in FIG. 3, a drive module 102 is suitable for such a connection mode or drive mode of the first and the second clock control terminals CK1 and CK2.

In FIG. 3, the first clock control terminal CK1 of the previous-stage drive module 101 is driven by the first clock signal CLK, but the second clock control terminal CK2 thereof is driven by the inverted second clock signal CLKB, in the contrast, the first clock control terminal CK1 of the next-stage drive module 102 is driven by the second clock signal CLKB, but the second clock control terminal CK2 thereof is driven by the first clock signal CLK, in other words, the connection modes of the clock control terminals in two adjacent drive modules are opposite, the introducing for this point will be described in detail in the follows.

In FIG. 2, input a high-level reference voltage VDD to the second end of the second and the seventh transistors (M2 and M7) in parallel and the second end of the fourth and the fifth transistors (M4 and M5) in parallel, and input the reference voltage VDD to the second end of the sixth transistor M6. For the plurality of drive modules which are in multiple stages, in a selected current-stage drive module, the first end of the first transistor M1 thereof is used to receive an input signal IN, we define the input signal IN of the current-stage drive module is essentially as an output signal Sₙ₋₁ of the previous-stage drive module of the current-stage drive module, so the first end of the first transistor M1 of the current-stage drive module should be coupled to the second common node N2 of the previous-stage drive module, to receive the output signal Sₙ₋₁ of the previous-stage drive module.

Similarly, still in the selected current-stage drive module, the gate control terminal of the seventh transistor M7 thereof is used to receive a reset signal RESET, we define the reset signal RESET of the current-stage drive module is essentially as an output signal Sₙ₊₁ of the next-stage drive module of the current-stage drive module, so the gate control terminal of the seventh transistor M7 of the current-stage drive module should be coupled to the second common node N2 of the next-stage drive module, to receive the output signal Sₙ₊₁ of the next-stage drive module. Meanwhile, the output signal Sₙ of the current-stage drive module serves as the reset signal RESET of the previous-stage drive module relative to the current-stage drive module and the input signal IN of the next-stage drive module relative to the current-stage drive module.

A shift register or an integrated Gate on Array (GOA) should comprise a plurality of single drive modules which are in multiple stages, as shown in FIG. 2. As referred to FIG. 3, the plurality of drive modules configured in a cascade connecting mode are connected in series, the plurality of drive modules at least comprise the first-line drive module 101, the second-line drive module 102, the third-line drive module 103, the fourth-line drive module 104, . . . and the N^{th}-line drive module etc., these multistage drive modules are configured into a line in series. The drive modules of this cascade connecting mode meet some rules, for example, in FIG. 3, the output signal of the current-stage drive module 102 serves as a reset signal RESET of the adjacent previous-stage drive module 101, and at the same time, as an input signal IN of the adjacent next-stage drive module 103, wherein other drive modules 103, 104 follow such rules. More specially, the manufacture in practice would assign a frame of switch-on signal STP-1 to the input signal IN of the first-line drive module 101, accordingly, another similar frame of switch-on signal STP-2 is assigned to the reset signal RESET of the last-line drive module of the multistage drive modules, in the case which is not too strict, the reset signal RESET of the last-line drive module without input signal is allowed, but the output end thereof may be in an output state, i.e. a multi-out state.

In order to avoid the ambiguity or understanding deviation caused by the wordings, we define the positional relation between the current-stage drive module and the previous-stage drive module, and the positional relation between the current-stage drive module and the next-stage drive module, and the positional relation between the previous-stage drive module and the next-stage drive module. For example in FIG. 3, in addition to the special first-line and last-line drive modules, a current-stage drive module N (like 103) has a previous-stage drive module N−1 (like 102) adjacent thereof and a next-stage drive module N+1 (like 104) adjacent thereof, the N is a natural number greater than or equal to 2. For the two adjacent drive modules N and N+1 (such as 103 and 104), the drive module N (such as 103) belongs to the previous-stage drive module, and the drive module N+1 (such as 104) belongs to the next-stage drive module.

The following will depict in this example: the output signal S_{N} of a current-stage drive module N serves as a reset signal RESET of a previous-stage drive module N−1 adjacent thereof and meanwhile as a input signal IN of a next-stage drive module N+1 adjacent thereof. Also assume that in two adjacent drive modules N and N+1, the first clock control terminal CK1 of the previous-stage drive module N−1 is driven by the first clock signal CLK, and the second clock control terminal CK2 thereof is driven by the second clock signal CLKB, the first clock control terminal CK1 of the next-stage drive module N is driven by the second clock signal CLKB, and the second clock control terminal CK2 thereof is driven by the first clock signal CLK. In some optional embodiments, in multistage drive modules configured in a line, the first clock control terminals CK1 of drive modules 101, 103 . . . in odd are driven by the first clock signal CLK, and the second clock control terminals CK2 thereof are driven by the second clock signal CLKB. Relatively, the first clock control terminals CK1 of drive modules 102, 104 . . . in even are driven by the second clock signal CLKB, and the second clock control terminals CK2 thereof are driven by the first clock signal CLK.

Refer to FIG. 4, adopt a predetermined period (such as a conventional half-frame period) as an example to illustrate the working mechanism of multistage drive modules. During the predetermined period, the first clock signal CLK and the second clock signal CLKB are signals inverted to each other in each period, and the logic state of the first clock signal CLK in the next period contraries to the logic state thereof in a previous period, and so does the second clock signal CLKB, which shows the characteristics of the clock signals. Within the predetermined period, referring to a sequential control program performed in the first to the fifth period T1-T5, the shifting effect is caused by the periodic change of the first clock signal CLK and the second clock signal CLKB, wherein the first to the fifth period T1-T5 is continuous in the timeline. During the first, the third and the fifth period T1, T3, T5, the first clock signal CLK is at a logic low level state and the second clock signal CLKB is at a logic high level state. Similarly, during the second and the fourth T2, T4 of the time period, the first clock signal CLK is at a logic high level state and the second clock signal CLKB is at a logic low level state. In some optional embodiments, the first clock signal CLK or the second clock signal CLKB can reach the level such as 5.5V˜7.5V of the reference voltage VDD when at a high level, and can reduce to the level such as negative −7V˜−9V of the reference voltage VEE when at a low level.

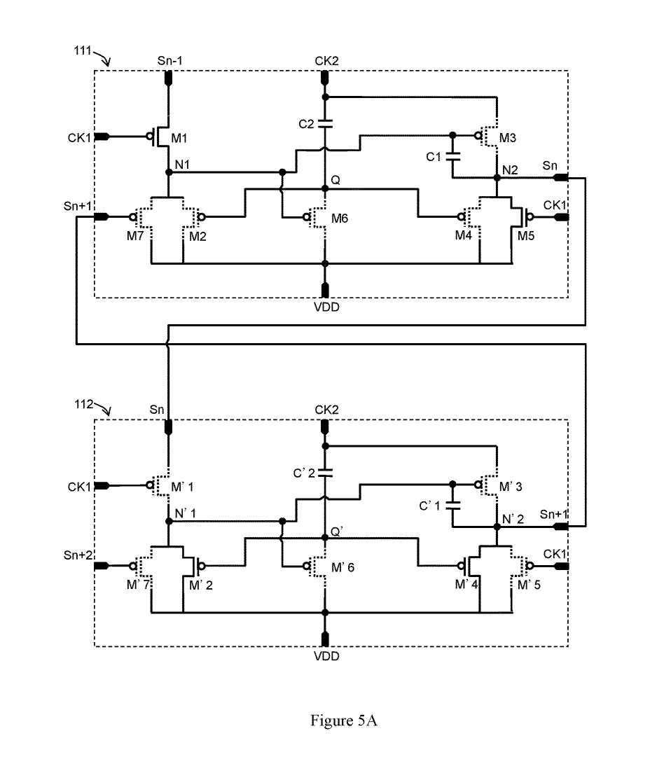

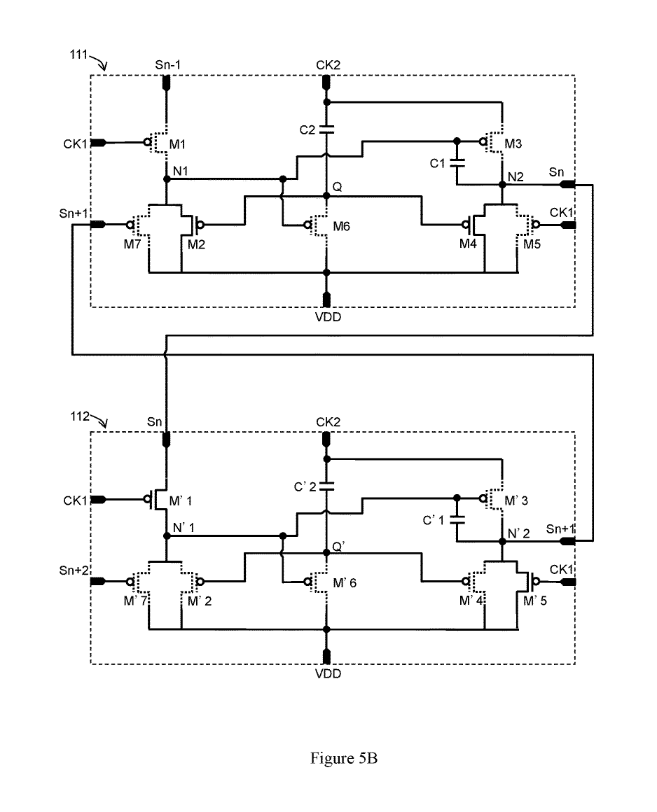

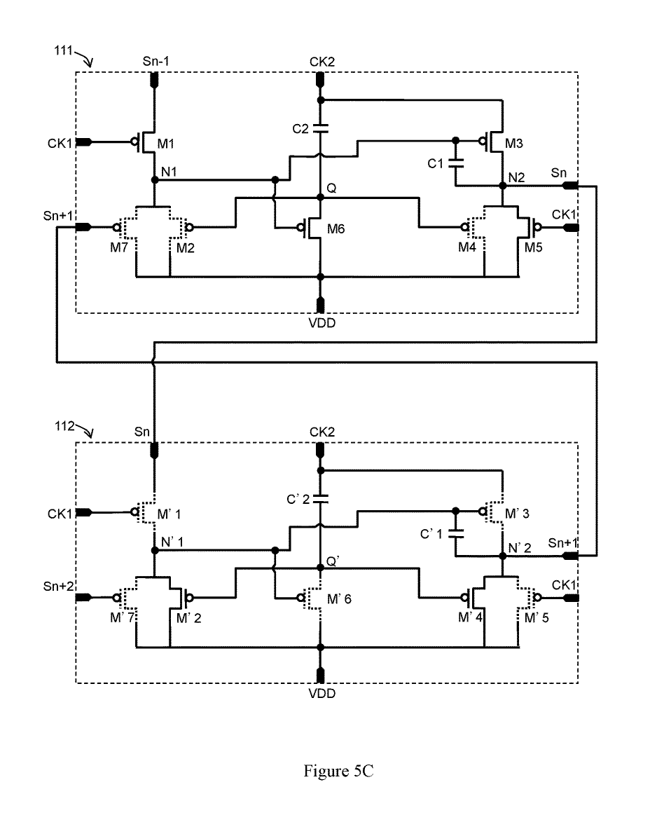

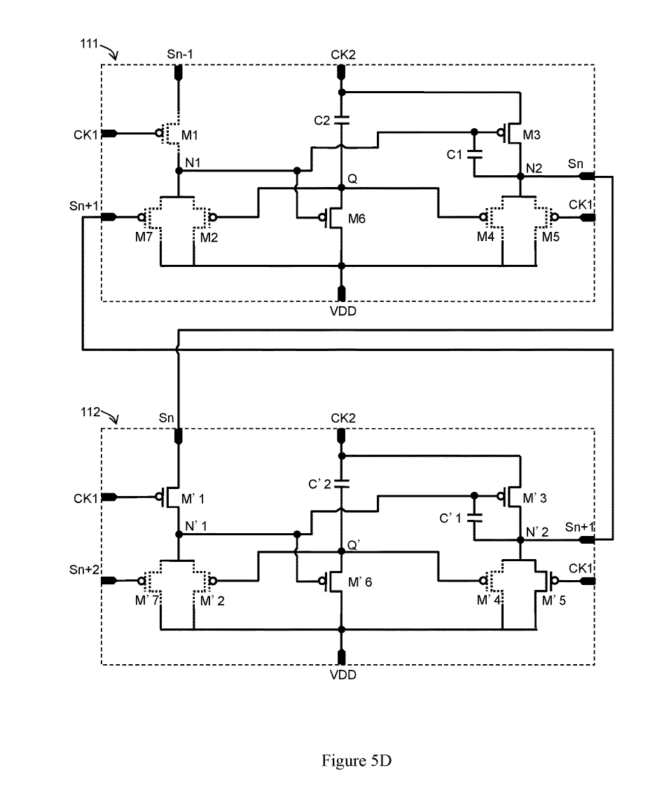

In FIG. 5A, the switch-on and switch-off response actions of each transistor of the current-stage drive module 111 and the adjacent next-stage drive module 112 are in accordance with the first period T1 in FIG. 4. Now set the output signals S₁ . . . S_{N-1}, S_{N}, S_{N+1} . . . of each stage drive module of the multistage drive modules in the first period T1 as an initialized high level. For the current-stage drive module 111, the gate of the first transistor M1 and the gate of the fifth transistor M5 are at a low potential state of the first clock signal CLK, and then the first transistor M1 and the fifth transistor M5 are switched on. Gates of the third transistor M3 and the sixth transistor M6 are connected to an input signal IN of the first end of the switch-on first transistor M1 (i.e. the output signal S_{N-1} of the previous-stage drive module of the drive module 111), in the mean time, the high level potential of the output signal S_{N-1} switches off the third transistor M3 and the sixth transistor M6, meanwhile, the high potential level of the output signal S_{N-1} of the previous-stage drive module of the drive module 111 is stored at the first common node N1 by the first capacitor C1. At this time, since the second clock signal CLKB connected to the first end of the second capacitor C2 is a high level, then the coupling effect generated by the second capacitor C2 will restrain the third common node Q of the second end of the second capacitor C2 at a high potential, so that the second transistor M2 and the fourth transistor M4 are switched off as the gates thereof are located at the high potential of the third common node Q.

Moreover, as the gate of the seventh transistor M7 is connected to the second common node N′2 of the next-stage drive module 112, and the output signal S_{N+1} of the drive module 112 is a high level so that the seventh transistor M7 is switched off, thus the output signal S_{N} of the current-stage drive module 111 is actually the high-level reference voltage VDD input by the second end of the switch-on fifth transistor M5, and at this time, by means of the holding action of voltage of the first capacitor C1, the Bootstrapping will synchronously pushes up the voltage level at the first common node N1 since the output signal S_{N} is a high level.

In FIG. 5A, for the next-stage drive module 112, the gate of the first transistor M′1 and the gate of the fifth transistor M′5 are at a high potential state of the second clock signal CLKB, so the first transistor M′1 and the fifth transistor M′5 are switched off. The high level reserved at the first common node N′1 by the action of the previous frame will switch off the third transistor M′3 and the sixth transistor M′6, and the first clock signal CLK input by the first end of the second capacitor C′2 is a low level, as the coupling effect generated by the second capacitor C′2, the third common node Q′ at the second end of the second capacitor C′2 is restrained in a low logic level, therefore the second transistor M′2 and the fourth transistor M′4 in which the gates connecting to the third common node Q′ are switched on. And the third transistor M′3 and the sixth transistor M′6 are sure to be switched off since the gates thereof connecting to the reference voltage VDD of the second end of the switch-on second transistor M′2. At the same time, the high level of the reference voltage VDD is synchronously stored at the first common node N′1 by the first capacitor C′1.

Moreover, the gate of the seventh transistor M′7 is connected to the second common node of the next-stage drive module of the drive module 112, and the output signal S_{N+2} of the next-stage drive module of the drive module 112 is a high level so that the seventh transistor M′7 is switched off. Therefore the output signal S_{N+1} of the drive module 112 is in essence the high-level reference voltage VDD input by the second end of the switch-on fourth transistor M′4.

FIG. 5B is responses of each transistor caused by the second period T2 in FIG. 4, and the second period T2 follows the first period T1, the output signals S₁ . . . S_{N-1}, S_{N}, S_{N+1} . . . of each drive module are still at the initialized high level respectively. Relative to the current-stage drive module 111, the gate of the first transistor M1 and the gate of the fifth transistor M5 are at a high potential state of the first clock signal CLK, therefore the first transistor M1 and the fifth transistor M5 are switched off. The third transistor M3 and the sixth transistor M6 are switched off since the gates thereof are at a high level of the first common node N1 stored by the first capacitor C1, meanwhile, as the second clock signal CLKB of the first end of the second capacitor C2 is a low level, thus the coupling effect generated by the second capacitor C2 restrains the third common node Q of the second end of the second capacitor C2 in a low potential, so that the second transistor M2 and the fourth transistor M4 be switched on because the gates thereof are located at the low potential of the third common node Q, the switch-on second transistor M2 ensures the high level standard of the first common node N1. Moreover, the gate of the seventh transistor M′7 is connected to the second common node N2 of the next-stage drive module, and the output signal S_{N+1} of the drive module 112 is a high level so that the seventh transistor M′7 is switched off. Therefore the output signal S_{N} of the current-stage drive module 111 is in essence the high-level reference voltage VDD input by the second end of the switched-on fourth transistor M4.

In FIG. 5B, for the next-stage drive module 112, the gate of the first transistor M′1 and the gate of the fifth transistor M′5 are located at a low potential state of the second clock signal CLKB, so that the first transistor M′1 and the fifth transistor M′5 are switched on. The high-level output signal S_{N} of the drive module 111 is transferred to the first common node N′1 and the gate of the third transistor M′3 and the gate of the sixth transistor M′6 through the switch-on first transistor M′1, thus the third transistor M′3 and the sixth transistor M′6 are switched off, and the first capacitor C′1 will still store a high level at the first common node N′1. In addition, as the first clock signal CLK input by the first end of the second capacitor C′2 is a high level, the coupling effect generated by the second capacitor C′2 restrains the third common node Q′ at the second end of the second capacitor C′2 in a high level, so that the second transistor M′2 and the fourth transistor M′4 in which the gates connect to the third common node Q′ are switched off.

Moreover, the gate of the seventh transistor M′7 is connected to the second common node of the next-stage drive module of the drive module 112, and the output signal S_{N+2} of the next-stage drive module of the drive module 112 is a high level, so that the seventh transistor M′7 is switched off. The output signal S_{N+1} of the drive module 112 at this stage is in essence the high-level reference voltage VDD input by the second end of the switch-on fifth transistor M′5.

FIG. 5C is a response of each transistor triggered by the third period T3 in FIG. 4, and the third period T3 follows the second period T2, it is noted that the output signal S_{N-1} of the previous-stage drive module of the current-stage drive module 111 now turns into a low level, but the output signals S_{N} and S_{N+1} of the drive modules 111 and 112 are still at a high level. Relative to the current-stage drive module 111, the gate of the first transistor M1 and the gate of the fifth transistor M5 are at a low potential state of the first clock signal CLK, so that the first transistor M1 and the fifth transistor M5 are switched on. The gates of the third transistor M3 and the gate of the sixth transistor M6 are connected to an input signal IN (that is, the output signal S_{N-1} of the previous-stage drive module relative to the drive module 111) of the first end of the switch-on first transistor M1, and the low-level potential of the output signal S_{N-1} switches on the third transistor M3 and the sixth transistor M6. Meanwhile, the low potential level of the output signal S_{N-1} of the previous-stage drive module relative to the drive module 111 is stored at the first common node N1 by the first capacitor C1. At this time, the sixth transistor M6 are switched on, so that the third common node Q at the first end thereof are essentially connected to the reference voltage VDD through the sixth transistor M6, thus the second transistor M2 and the fourth transistor M4 are switched off as the gates thereof are located at the high potential of the third common node Q.

Moreover, the gate of the seventh transistor M′7 is connected to the second common node N′2 of the next-stage drive module 112, and the output signal S_{N+1} of the drive module 112 is a high level, so that the seventh transistor M′7 is switched off. At this stage the third transistor M3 is switched on, therefore the output signal S_{N} of the current-stage drive module 111 can connect to the high-potential second clock signal CLKB input by the first end of the third transistor M3, meanwhile the fifth transistor M5 is also switched on, which will ensure the stability of the high level state of the output signal S_{N} of the current-stage drive module 111, to maintain at the level of the reference voltage VDD input by the second end of the switch-on fifth transistor M5.

In FIG. 5C, for the next-stage drive module 112, the gate of the first transistor M′1 and the gate of the fifth transistor M′5 are located at a high potential state of the second clock signal CLKB, so that the first transistor M′1 and the fifth transistor M′5 are switched off. The high level reserved at the first common node N′1 switches off the third transistor M′3 and the sixth transistor M′6, and the first clock signal CLK input by the first end of the second capacitor C′2 is a low level, therefore the coupling effect generated by the second capacitor C′2 restrains the third common node Q′ at the second end of the second capacitor C′2 in a low level, so that the second transistor M′2 and the fourth transistor M′4 in which the gates are connected to the third common node Q′ are switch-on, the switch-on second transistor M′2 will ensure the level of the first common node N′1 maintain at the level of the reference voltage VDD input by the second end of the second transistor M′2. In addition, the gate of the seventh transistor M′7 is connected to the second common node of the next-stage drive module relative to the drive module 112, and the output signal S_{N+2} of the next-stage drive module relative to the drive module 112 is a high level, so that the seventh transistor M′7 is switched off. At this stage the output signal S_{N+1} of the drive module 112 is in essence the high-level reference voltage VDD input by the second end of the switch-on fourth transistor M′4.

FIG. 5D is a response of each transistor triggered by the fourth period T4 in FIG. 4, and the fourth period T4 follows the third period T3. Note that in the above-mentioned predetermined period time, the output signal S_{N-1} of the previous-stage drive module relative to the current-stage drive module 111 is inverted into a low level in the third period T3, but the output signal S_{N-1} had a high level logic state before the third period T3 and will return to high level logic state after the third period T3. During the period T4, the output signal S_{N+1} of the drive module 112 and the output signal S_{N+2} of the next-stage drive module relative to the drive module 112 are still at high level, and the output signal S_{N-1} is also at a high level. For the current-stage drive module 111, the gate of the first transistor M1 and the gate of the fifth transistor M5 are at a high potential state of the first clock signal CLK, so that the first transistor M1 and the fifth transistor M5 are switched off. The third transistor M3 and the sixth transistor M6 are switched on since the gates thereof are located at a low level state of the first common node N1 stored by the first capacitor C1.

Meanwhile, the switch-on sixth transistor M6 makes the third common node Q located at the first end thereof connect to the reference voltage VDD input by the second end of the sixth transistor M6, thus the second transistor M2 and the fourth transistor M4 are switched off since the gates thereof are located at a high level of the third common node Q. In addition, the gate of the seventh transistor M′7 is connected to the second common node N′2 of the next-stage drive module 112, and the output signal S_{N+1} of the drive module 112 is a high level, so that the seventh transistor M′7 is switched off. At this stage the third transistor M3 is switched-on, therefore the second common node N2 of the current-stage drive module 111 can connect to the low-level second clock signal CLKB input by the first end of the third transistor M3, and that ensures the output signal S_{N} of the current-stage drive module 111 maintain at a low voltage level of the second clock signal CLKB input by the first end of the third transistor M3, such as, the low voltage level is equal to the reference voltage VEE.

In FIG. 5D, for the next-stage drive module 112, the gate of the first transistor M′1 and the gate of the fifth transistor M′5 are located at a low potential state of the second clock signal CLKB, so that the first transistor M′1 and the fifth transistor M′5 are switched on. As the output signal S_{N} input by the first end of the switch-on first transistor M′1 maintains at a low level state, thus the third transistor M′3 and the sixth transistor M′6 are switched on, and the first capacitor C′1 stores a low level at the first common node N′1. The switch-on sixth transistor M′6 makes the third common node Q′ at the first end thereof connect to the reference voltage VDD input by the second end of the sixth transistor M6, thus the second transistor M′2 and the fourth transistor M′4 are switched off since the gates thereof are located at the high potential of the third common node Q′. In addition, the gate of the seventh transistor M′7 is connected to the second common node of the next-stage drive module relative to the drive module 112, and the output signal S_{N+2} of the next-stage drive module relative to the drive module 112 is a high level, so that the seventh transistor M′7 is switched off. At this stage the third transistor M′3 is switched on, therefore the second common node N′2 of the drive module 112 can connect to the high-potential second clock signal CLKB input by the first end of the third transistor M′3, meanwhile the fifth transistor M′5 is switched on, which ensures stability of the high level state of the output signal S_{N+1} of the drive module 112, and maintain it at the level of the reference voltage VDD input by the second end of the switch-on fifth transistor M′5.

FIG. 5E is a response of each transistor triggered by the fifth period T5 in FIG. 4, and the fifth period T5 follows the fourth period T4, it is noted that the output signal S_{N-1} of the previous-stage drive module relative to the current-stage drive module 111 returns to a high level at this stage. For the current-stage drive module 111, the gate of the first transistor M1 and the gate of the fifth transistor M5 are located at a low potential state of the first clock signal CLK, so that the first transistor M1 and fifth transistor M5 are switched on. The gate of the third transistor M3 and the gate of the sixth transistor M6 are connected to an input signal IN (that is, the output signal S_{N-1} of the previous-stage drive module relative to the drive module 111) of the first end of the switch-on first transistor M1, so that the high-level potential of the output signal S_{N-1} switches off the third transistor M3 and the sixth transistor M6. At this time, since the second clock signal CLKB connected to the first end of the second capacitor C2 is a high level, therefore the coupling effect generated by the second capacitor C2 restrains the third common node Q of the second end of the second capacitor C2 in a high potential, thus the second transistor M2 and the fourth transistor M4 are switched off as the gates thereof are located at the high potential of the third common node Q.

In addition, the gate of the seventh transistor M7 is connected to the second common node N′2 of the next-stage drive module 112, and the output signal S_{N+1} of the drive module 112 is a low level (the following will introduce the reason why the output signal S_{N+1} reverses to the low level), so that the seventh transistor M′7 is switched on, thus the first common node N1 is connected to the high-level reference voltage VDD input by the second end of the seventh transistor M7 through the switch-on seventh transistor M7, and that ensures the third transistor M3 and the sixth transistor M6 are switched off. At this stage the output signal S_{N} of the current-stage drive module 111 is in essence the high-level reference voltage VDD input by the second end of the switch-on fifth transistor M5.

In FIG. 5E, for the next-stage drive module 112, the gate of the first transistor M′1 and the gate of the fifth transistor M′5 are located at a high potential state of the second clock signal CLKB, so that the first transistor M′1 and the fifth transistor M′5 are switched off. In view of the first capacitor C′1 being stored at a low level at the first common node N′1 as shown in FIG. 5D, thus the third transistor M′3 and the sixth transistor M′6 are switched on. The switch-on sixth transistor M′6 makes the third common node Q′ at the first end thereof connect to the reference voltage VDD input by the second end of the sixth transistor M′6, thus the second transistor M′2 and the fourth transistor M′4 are switched off since the gates thereof are located at the high potential of the third common node Q′. In addition, the gate of the seventh transistor M′7 is connected to the second common node of the next-stage drive module relative to the drive module 112, and the output signal S_{N+2} of the next-stage drive module relative to the drive module 112 is a high level, so that the seventh transistor M′7 is switched off. At this stage the third transistor M′3 is switched on, therefore the second common node N′2 of the drive module 112 can connect to the low-potential second clock signal CLKB input by the first end of the third transistor M′3, for example the low-potential is equal to the reference voltage VEE, so as to ensure the output signal S_{N+1} of the drive module 112 is equal to the reference voltage VEE input by the first end of the switch-on third transistor M′3. Obviously a logic low level of the output signal S_{N} generated by triggering the drive module 111 in the fourth period T4 is shifted to the output signal S_{N+1} of the drive module 112 in the fifth period T5.

Referring to FIG. 4, during a period following the fifth period T5, the first clock signal CLK is inverted to a high level and the second clock signal CLKB is inverted to a low level, that is to say, during the periods other than performing the sequential control program of T1-T5 within the whole predetermined period, the first clock signal CLK and the second clock signal CLKB repeat the actions of the period T2 and T1, but the output signal S_{N} of the current-stage drive module 111 maintains at a high level of VDD. For any adjacent two of the plurality of drive modules N−1, N, the output signal S_{N-1} of the previous-stage drive module N−1 has a high level logic state before a predetermined period T3, but S_{N-1} shifts to a low level logic state during the predetermined period T3 and returns to the high level logic state after the predetermined period T3, while the output signal S_{N} of the adjacent next-stage drive module N has a high level logic state before the period T4 following the predetermined period T3, but S_{N} shifts to a low level logic state during the next period T4 and returns to the high level logic state after the next period of time T4. Such a rule applies to any of the adjacent two of the plurality of drive modules, since in essence, shift is one of the objectives of the multi-stage drive modules of the invention.

Finally we find the combination of the output signals S₁ . . . S_{N-1}, S_{N}, S_{N+1} . . . of the plurality of drive modules constitutes a series of non-overlapping sequential pulse signals. For example, select any one of the output signals S_{N-1}, which has a low level state during the predetermined period T3, and the adjacent output signal S_{N} has a low level state during the next period T4, but the output signals S_{N-1} and S_{N} will not be overlapped at the same period so as to enter a low level state synchronously. The series of non-overlapping sequential pulse signals [S₁ . . . S_{N-1}, S_{N}, S_{N+1} . . . ] generated by the drive circuit GOA are typically used as row gate control signals of the pixel circuit array, for example the gate control signals provided for the AMOLED pixel circuit.

In some optional embodiments, the drive module 101 is a first drive module of a line, that is, the drive module 101 has no adjacent previous-stage drive module, so that an input signal (e.g., an output signal S_{N-1} to be provided) coupled by the input signal IN of the drive module 101 cannot be captured from the previous-stage drive module, the input signal can use a frame of switching on signal STP-1 as the output signal S_{N-1} to provide to the drive module 101, that is, use the frame of switching on signal STP-1 (the output signal S_{N-1}) transmitted by other drive elements to trigger the first drive module 101 in FIG. 4, and to generate gradual shifting effect of the output signal S_{N-1} during the subsequent each period.

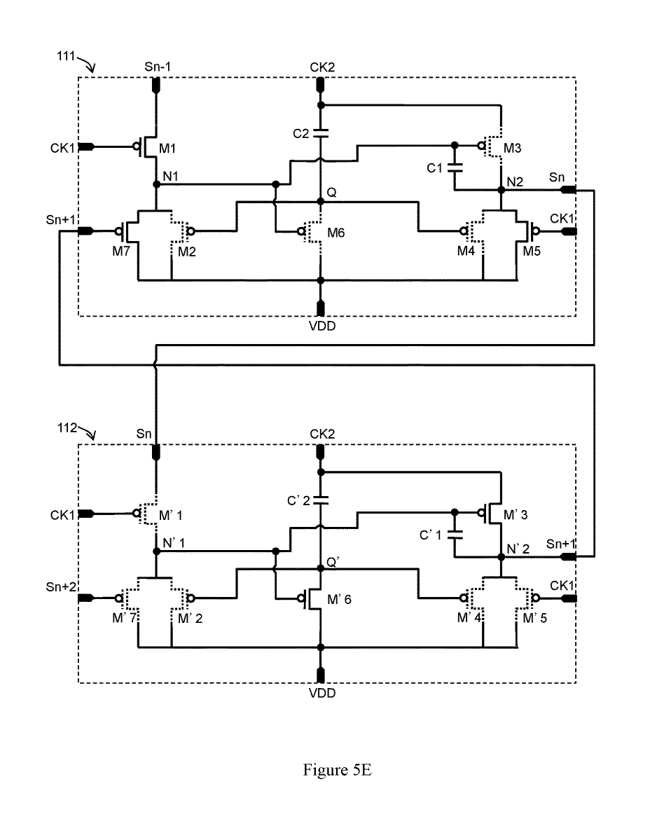

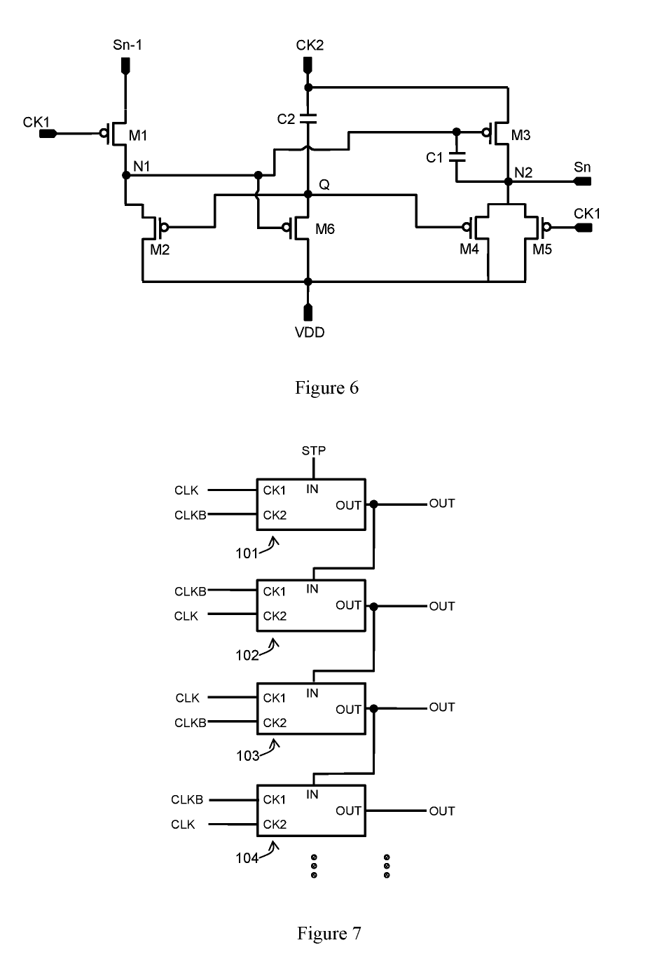

Obviously, from the embodiments of FIGS. 5A-5E, we can find the fourth transistor M4 and the fifth transistor M5 switchover to each other and alternately pull up the output signal S_{N}, thus the issue about shifting of the threshold voltage caused by the single transistor M13 being switch-on for a long time is addressed. In another optional embodiment of FIG. 6, it just omits the seventh transistor M7 compared with the embodiment of FIG. 2, that is, the first transistor M1 and the second transistor M2 are connected in series directly, therefore between the first common node N1 and the second end of the second transistor M2, no transistor is required to be connected to the second transistor M2 in parallel. The cascade connecting mode of multistage drive modules is shown in FIG. 7 accordingly, in comparison with the embodiment of FIG. 3, the difference only lies, in adjacent two of the plurality of drive modules N and N+1, the output signal S_{N} of the previous-stage drive module N can be transferred to the first end of the first transistor M1 of the next-stage drive module N+1, to be served as the input signal IN of the next-stage drive module N+1, however, the next-stage drive module N+1 does not need to feedback a reset signal to the omitted seventh transistor M7 of the previous-stage drive module N.

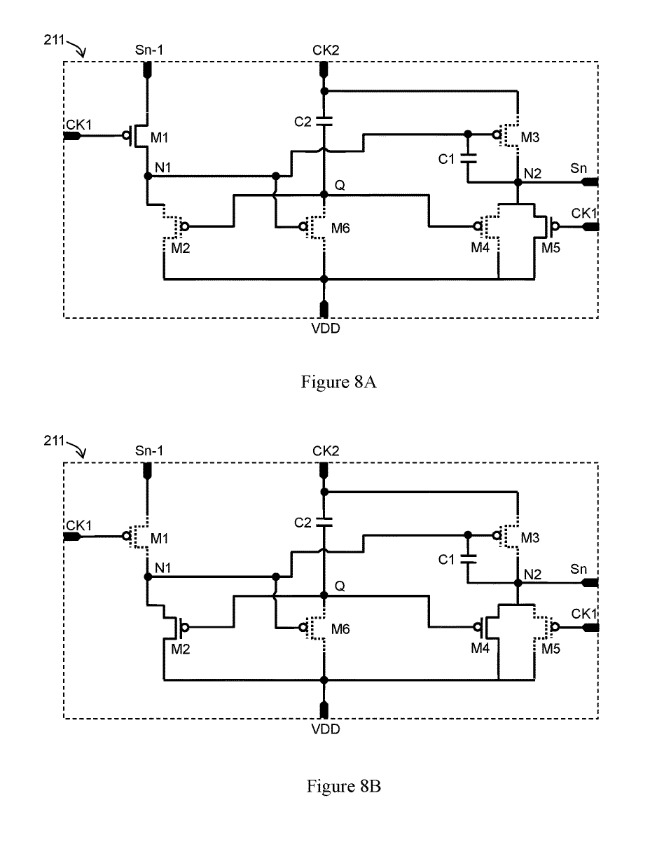

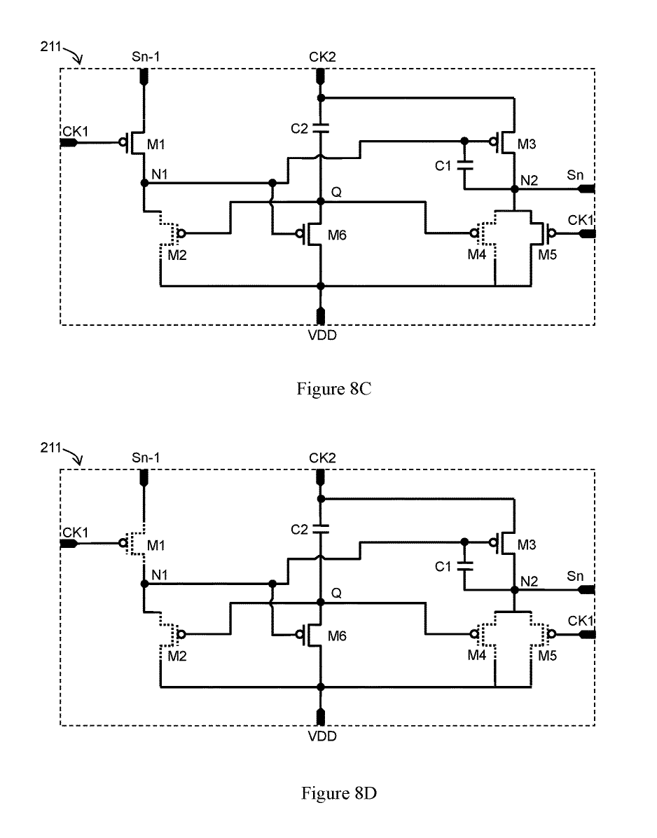

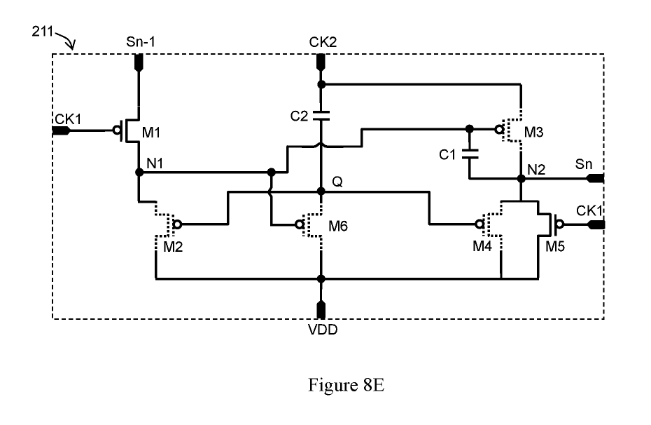

On the basis of the above interpretation, FIGS. 8A-8E will not repeat switching actions between transistors of the adjacent two of the plurality of drive modules N and N+1, and just briefly describe a drive module N.

In the drive module 211 of FIG. 8A, during the phase T1, the gate of the first transistor M1 and the gate of the fifth transistor M5 are located at a low potential state of the first clock signal CLK, so that the first transistor M1 and the fifth transistor M5 are switched on. The gate of the third transistor M3 and the gate of the sixth transistor M6 are connected to an input signal IN (that is, the output signal S_{N-1}) of the first end of the switch-on first transistor M1, so that the high-level potential of the output signal S_{N-1} switches off the third transistor M3 and the sixth transistor M6, meanwhile the high potential level of the output signal S_{N-1} is stored at the first common node N1 by the first capacitor C1. Since the second clock signal CLKB connected to the first end of the second capacitor C2 is a high level, therefore the coupling effect generated by the second capacitor C2 restrains the third common node Q in a high potential, thus the second transistor M2 and the fourth transistor M4 are switched off because the gates thereof are located at the high potential of the third common node Q. Thus the output signal S_{N} of the drive module 211 is in essence the high-level reference voltage VDD input by the second end of the switch-on fifth transistor M5.

During the phase T2 of FIG. 8B, the gate of the first transistor M1 and the gate of the fifth transistor M5 are located at a high potential state of the first clock signal CLK, so that the first transistor M1 and the fifth transistor M5 are switched off. The third transistor M3 and the sixth transistor M6 are switched off because the gates thereof are located at a high level of the first common node N1 stored by the first capacitor C1. Meanwhile, as the second clock signal CLKB located at the first end of the second capacitor C2 is a low level, therefore the coupling effect generated by the second capacitor C2 restrains the third common node Q of the second end of the second capacitor C2 in a low potential, so that the second transistor M2 and the fourth transistor M4 are switched on, and the switch-on second transistor M2 ensures the high level of the first common node N1. Thus the output signal S_{N} of the drive module 211 is in essence the high level reference voltage VDD input by the second end of the switch-on fourth transistor M4.

During the phase T3 of FIG. 8C, the gate of the first transistor M1 and the gate of the fifth transistor M5 are at a low potential state of the first clock signal CLK, so that the first transistor M1 and the fifth transistor M5 are switched on. The gate of the third transistor M3 and the gate of the sixth transistor M6 are connected to an input signal IN (that is, the output signal S_{N-1}) of the first end of the switch-on first transistor M1, so that the low level potential of the output signal S_{N-1} switches on the third transistor M3 and the sixth transistor M6, meanwhile the low potential of the output signal S_{N-1} is stored at the first common node N1 by the first capacitor C1. As the sixth transistor M6 is switched on, the third common node Q at the first end thereof connects to the reference voltage VDD substantially through the sixth transistor M6, so that the second transistor M2 and the fourth transistors M4 are switched off since the gates thereof are located at a high level. At this stage the third transistor M3 is switched on, therefore the output signal S_{N} of the current-stage drive module 111 can connect to the high-potential second clock signal CLKB input by the first end of the third transistor M3, meanwhile the fifth transistor M5 is switched on, which ensures stability of the high level stage of the output signal S_{N} of the current-stage drive module 111, and the output signal S_{N} maintains at the level of the reference voltage VDD input by the second end of the switch-on fifth transistor M5.

During the phase T4 of FIG. 8D, the gate of the first transistor M1 and the gate of the fifth transistor M5 are at a high potential state of the first clock signal CLK, so that the first transistor M1 and the fifth transistor M5 are switched off. The third transistor M3 and the sixth transistors M6 are switched on since the gates thereof are located at a low level state of the first common node N1 stored by the first capacitor C1. Meanwhile the switch-on sixth transistor M6 makes the third common node Q at the first end thereof connects to the reference voltage VDD, so that the second transistor M2 and the fourth transistor M4 are switched off since the gates thereof are located at a high level. As the third transistor M3 is switched on, therefore the second common node N2 of the drive module 211 can connect to the low-potential second clock signal CLKB input by the first end of the third transistor M3, thus it ensures the output signal S_{N} of the drive module 211 maintain at the low voltage level of the second clock signal CLKB, such as the S_{N} is equal to the reference voltage VEE.

During the phase T5 of FIG. 8E, the gate of the first transistor M1 and the gate of the fifth transistor M5 are located at a low potential state of the first clock signal CLK, so that the first transistor M1 and the fifth transistor M5 are switched on. The gates of the third transistor M3 and the gate of the sixth transistor M6 are connected to an input signal IN (that is, the output signal S_{N-1}) of the first end of the switch-on first transistor M1, so that the high level potential of the output signal S_{N-1} switches off the third transistor M3 and the sixth transistor M6. Meanwhile, as the second clock signal CLKB connected to the first end of the second capacitor C2 is a high level, therefore the coupling effect generated by the second capacitor C2 restrains the third common node Q of the second end of the second capacitor C2 in a high potential, so that the second transistor M2 and the fourth transistor M4 are switched off. During this phase the output signal S_{N} of the drive module 211 is in essence the high-level reference voltage VDD input by the second end of the switch-on fifth transistor M5.

### Embodiment 2

This embodiment provides an AMOLED display (e.g., LCD panel, electronic paper, OLED panel and TV screen and so on), and the display can comprises a display drive device as recorded in Embodiment 1, and the AMOLED display can further comprise an array substrate provided with a display area and a GOA area, a display module, such as OLED etc., is configured on the display area of the array substrate, the display drive device, as recorded in Embodiment 1, can be configured on the GOA area of the array substrate, so that the display drive device drives the display module to emit light. That is, the AMOLED display recorded in the present embodiment comprises the technical solutions of the display drive device as recorded in Embodiment 1, and here we do not describe the same technical features for concise elaboration any more, but those skilled in the art shall be aware of the relevant technical features recorded in Embodiment 1 are suitable for the technical solutions of the present embodiment.

The foregoing is only the preferred embodiments of the invention, not thus limiting embodiments and scope of the invention, those skilled in the art should be able to realize that the schemes obtained from the content of specification and Figures of the invention are within the scope of the invention.

What is claimed is:

1. A display drive device, comprising a plurality of drive modules which are in multiple stages, each of the drive modules comprising:
a first transistor and a second transistor connected to each other in series, and a first node configured at an interconnection point between the second transistor and the first transistor;
a third transistor configured with a control terminal, and the first node being connected to the control terminal of the third transistor;
a fourth transistor and a fifth transistor connected to each other in parallel, and a second node configured at an interconnection point between the fifth transistor and the fourth transistor;
a first capacitor connected between the first node and the second node;
wherein, the third transistor is connected to the second node, so that an output signal is generated at the second node.

2. The display drive device according to claim 1, wherein each of the drive modules further comprising:
a second capacitor and a sixth transistor connected to each other in series, a control terminal of the sixth transistor being connected to the first node; and
a third node configure at an interconnection point between a first end of the sixth transistor and a second end of the second capacitor, and the third node being connected to a control terminal of the second transistor and a control terminal of the fourth transistor respectively;
a reference voltage end, connected to a second end of the second transistor, a second end of the fourth transistor, a second end of the fifth transistor and a second end of the sixth transistor respectively;
wherein, a first end of the second capacitor is connected to a first end of the third transistor, and a second end of the third transistor is connected to the second node.

3. The display drive device according to claim 2, wherein a second end of the first transistor and a first end of the second transistor are connected to the first node, and a first end of the first transistor is used to receive an input signal, a control terminal of the first transistor and a control terminal of the fifth transistor are connected to a first clock control terminal of each of the drive modules, the first end of the second capacitor and the first end of the third transistor are connected to a second clock control terminal of each of the drive modules.

4. The display drive device according to claim 3, wherein between two adjacent of the plurality of drive modules:
an output signal end of a previous-stage drive module is connected to the first end of the first transistor of a next-stage drive module, so that an output signal of the previous-stage drive module is used for an input signal of the next-stage drive module.

5. The display drive device according to claim 3, wherein each of the drive modules further comprises:
a seventh transistor, connected to the second transistor in parallel;
wherein, a first end of the seventh transistor is connected to the first node, and a second end of the seventh transistor is connected to the reference voltage end.

6. The display drive device according to claim 5, wherein between two adjacent of the plurality of drive modules:
an output signal of a previous-stage drive module is transmitted to the first end of the first transistor of a next-stage drive module, so that the output signal is used as an input signal of the next-stage drive module; and
an output signal of the next-stage drive module is transmitted to a control terminal of the seventh transistor of the previous-stage drive module, so that the output signal is used as a reset signal of the next-stage drive module.

7. The display drive device according to claim 3, wherein between two adjacent of the plurality of drive modules:
the first clock control terminal of a previous-stage drive module is driven by a first clock signal, and the second clock control terminal of the previous-stage drive module is driven by a second clock signal inverted from the first clock signal; and
the first clock control terminal of a next-stage drive module is driven by the second clock signal, and the second clock control terminal of the next-stage drive module is driven by the first clock signal.

8. The display drive device according to claim 5, wherein between two adjacent of the plurality of drive modules:
the first clock control terminal of a previous-stage drive module is driven by a first clock signal, and the second clock control terminal of the previous-stage drive module is driven by a second clock signal inverted from the first clock signal; and
the first clock control terminal of a next-stage drive module is driven by the second clock signal, and the second clock control terminal of the next-stage drive module is driven by the first clock signal.

9. The display drive device according to claim 4, wherein among the plurality of drive modules arranged in series:
the first clock control terminals of the plurality of drive modules in odd are driven by a first clock signal, and the second clock control terminals of the plurality of drive modules in odd are driven by a second clock signal complemented to the first clock signal; and
the first clock control terminals of the plurality of drive modules in even are driven by the second clock signal, and the second clock control terminals of the plurality of drive modules in even are driven by the first clock signal.

10. The display drive device according to claim 6, wherein among the plurality of drive modules arranged in series:
the first clock control terminals of the plurality of drive modules in odd are driven by a first clock signal, and the second clock control terminals of the plurality of drive modules in odd are driven by a second clock signal complemented to the first clock signal; and
the first clock control terminals of the plurality of drive modules in even are driven by the second clock signal, and the second clock control terminals of the plurality of drive modules in even are driven by the first clock signal.

11. The display drive device according to claim 2, wherein the first transistor, the second transistor, the third transistor, the fourth transistor, the fifth transistor and the sixth transistor are all PMOS (P-channel Metal Oxide Semiconductor) thin-film transistors.

12. The display drive device according to claim 5, wherein the first transistor, the second transistor, the third transistor, the fourth transistor, the fifth transistor, the sixth transistor and the seventh transistor are all PMOS thin-film transistors.

13. An AMOLED display, comprising a display drive device, the display drive device comprising a plurality of drive modules which are in multiple stages, each of the drive modules comprising:
a first transistor and a second transistor connected to each other in series, and a first node configured at an interconnection point between the second transistor and the first transistor;
a third transistor configured with a control terminal, and the first node being connected to the control terminal of the third transistor;
a fourth transistor and a fifth transistor connected to each other in parallel, and a second node configured at an interconnection point between the fifth transistor and the fourth transistor;
a first capacitor connected between the first node and the second node;
wherein, the third transistor is connected to the second node, so that an output signal is generated at the second node;
wherein, the AMOLED display further comprising:
an array substrate provided with a display area and a GOA (Gate on Array) area;
a display module configured on the display area of the array substrate; and
the display drive device being configured on the GOA area of the array substrate, so as to drive the display module to emit light.

14. The AMOLED display according to claim 13, wherein each of the drive modules further comprising:
a second capacitor and a sixth transistor connected to each other in series, a control terminal of the sixth transistor being connected to the first node; and
a third node configure at an interconnection point between a first end of the sixth transistor and a second end of the second capacitor, and the third node being connected to a control terminal of the second transistor and a control terminal of the fourth transistor respectively;
a reference voltage end, connected to a second end of the second transistor, a second end of the fourth transistor, a second end of the fifth transistor and a second end of the sixth transistor respectively;
wherein, a first end of the second capacitor is connected to a first end of the third transistor, and a second end of the third transistor is connected to the second node.

15. The AMOLED display according to claim 14, wherein a second end of the first transistor and a first end of the second transistor are connected to the first node, and a first end of the first transistor is used to receive an input signal, a control terminal of the first transistor and a control terminal of the fifth transistor are connected to a first clock control terminal of each of the drive modules, the first end of the second capacitor and the first end of the third transistor are connected to a second clock control terminal of each of the drive modules.

16. The AMOLED display according to claim 15, wherein between two adjacent of the plurality of drive modules:
an output signal end of a previous-stage drive module is connected to the first end of the first transistor of a next-stage drive module, so that an output signal of the previous-stage drive module is used for an input signal of the next-stage drive module.

17. The AMOLED display according to claim 15, wherein each of the drive modules further comprises:
a seventh transistor, connected to the second transistor in parallel;
wherein, a first end of the seventh transistor is connected to the first node, and a second end of the seventh transistor is connected to the reference voltage end.

18. The AMOLED display according to claim 17, wherein between two adjacent of the plurality of drive modules:
an output signal of a previous-stage drive module is transmitted to the first end of the first transistor of a next-stage drive module, so that the output signal is used as an input signal of the next-stage drive module; and
an output signal of the next-stage drive module is transmitted to a control terminal of the seventh transistor of the previous-stage drive module, so that the output signal is used as a reset signal of the next-stage drive module.

19. The AMOLED display according to claim 15, wherein between two adjacent of the plurality of drive modules:
the first clock control terminal of a previous-stage drive module is driven by a first clock signal, and the second clock control terminal of the previous-stage drive module is driven by a second clock signal inverted from the first clock signal; and
the first clock control terminal of a next-stage drive module is driven by the second clock signal, and the second clock control terminal of the next-stage drive module is driven by the first clock signal.

20. The AMOLED display according to claim 17, wherein between two adjacent of the plurality of drive modules:
the first clock control terminal of a previous-stage drive module is driven by a first clock signal, and the second clock control terminal of the previous-stage drive module is driven by a second clock signal inverted from the first clock signal; and
the first clock control terminal of a next-stage drive module is driven by the second clock signal, and the second clock control terminal of the next-stage drive module is driven by the first clock signal.
